(19) United States
(12) Patent Application Publication
(10) Pub. No.: US 2020/0281070 A1
(43) Pub. Date: Sep. 3, 2020

(54) HIGH SPEED HIGH POWER LASER ASSEMBLY WITH CAVITY

(71) Applicant: Analog Devices International Unlimited Company, Limerick (IE)

(72) Inventor: Sinan Alemdar, Istanbul (TR)

(21) Appl. No.: 16/435,297

(22) Filed: Jun. 7, 2019

Related U.S. Application Data
(60) Provisional application No. 62/812,869, filed on Mar. 1, 2019.

(51) Int. Cl. H05K 1/02; H05K 1/18; H05K 1/11; H05K 3/40; H05K 3/30; H01S 5/022; H01S 5/024; H01S 5/042

(52) U.S. Cl. CPC H05K 1/0216; H05K 1/181; H05K 1/115; H05K 1/0206; H05K 3/4038; H05K 2201/10106; H01S 5/02276; H01S 5/02469; H01S 5/042; H01S 5/0226; H05K 3/305

(57) ABSTRACT

An electronic circuit assembly comprises a circuit substrate including a top surface, a bottom surface, and a cavity formed at an edge of the circuit substrate that exposes an intermediate surface between the top surface and the bottom surface of the circuit substrate; and a laser diode including a top surface, a bottom surface, and a side surface; wherein the bottom surface of the laser diode is arranged on the intermediate surface of the circuit substrate.

### CLAIM OF PRIORITY

This application claims the benefit of priority to U.S. Provisional Application Ser. No. 62/812,869, filed Mar. 1, 2019, which is hereby incorporated by reference in its entirety.

### FIELD OF THE DISCLOSURE

This document relates generally to electronic circuits for optical applications, and in particular it relates to circuit assemblies that include a laser emitting diode.

### BACKGROUND

Electronic laser transmitter systems can include a laser driver and a laser emitting diode. The laser driver and laser diode connection can include significant undesirable circuit parasitics such as unwanted circuit capacitance or unwanted circuit inductance for example. The circuit parasitics can prevent fast rise times and fall times that are required for high power output within narrow pulses to stay within eye-safety limits. Additionally, unwanted circuit parasitics may cause high overshoot and undershoot especially in high power operation of the laser transmitter system. The high overshoot and undershot can cause distortion of the laser pulse shape and may damage the electronic circuitry.

### SUMMARY OF THE DISCLOSURE

This document relates generally to power management circuits and methods of their operation. An electronic circuit assembly according to various aspects includes a circuit substrate and a laser diode. The circuit substrate includes a top surface, a bottom surface, and a cavity formed at an edge of the circuit substrate that exposes an intermediate surface between the top surface and the bottom surface of the circuit substrate. The laser diode includes a top surface, a bottom surface, and a side surface. The bottom surface of the laser diode is arranged on the intermediate surface of the circuit substrate.

This section is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a block diagram of portions of a laser transmitter system.

FIGS. 2A and 2B are schematics of examples of laser driver circuit topologies to control a laser transmitter system.

FIG. 3 is a timing diagram of an example of turning on and turning off a low-side switch circuit.

FIGS. 4A-4C are examples of circuit assemblies including laser diodes.

FIG. 5 is another example of a circuit assembly including a laser diode.

FIG. 6 is a flow diagram of an example of a method of making a circuit assembly that includes a laser diode.

### DETAILED DESCRIPTION

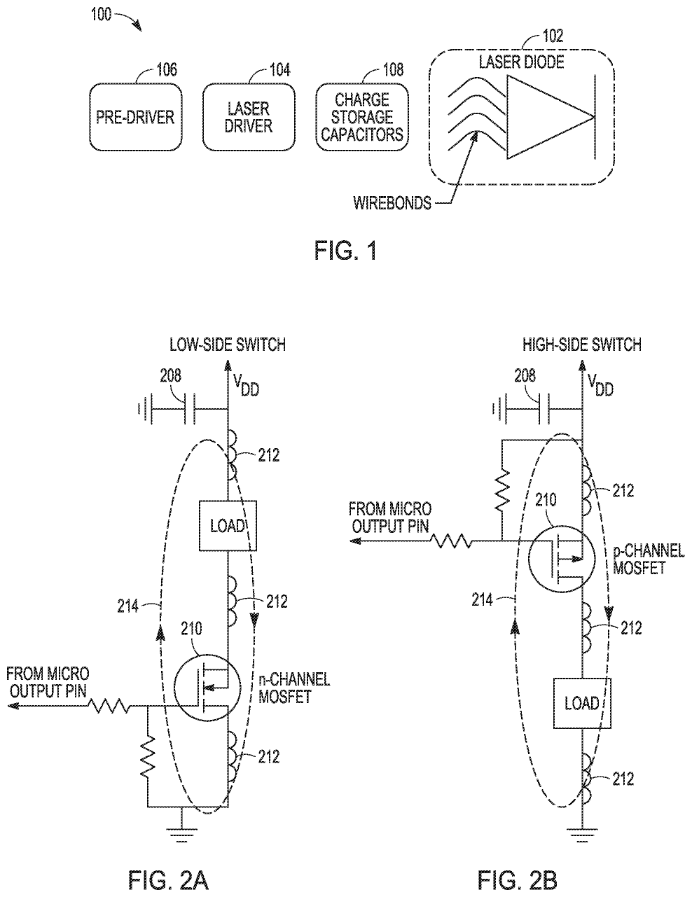

FIG. 1 is a block diagram of portions of a laser transmitter system 100. The system may be used in Laser Imaging Detection and Ranging (LIDAR) applications. The laser transmitter system 100 includes a laser diode 102 that converts electrical current to light energy. In certain aspects, the laser diode 102 is a vertical cavity surface emitting laser (VCSEL) diode that emits laser energy in a direction perpendicular to the top surface of the laser diode 102. In certain aspects, the laser diode 102 is an edge emitting laser (EEL) diode that emits laser energy in a direction perpendicular to a side surface of the laser diode 102. The system also includes a laser driver 104 that provides or drives the current through the laser diode 102 and can include a pre-driver 106 to provide drive for the laser driver 104. The laser transmitter system 100 can also include one or more charge storage capacitors 108 that stores the charge that is converted to the current that is provided to the laser diode 102. The system also includes wirebonds that attach the laser diode to the circuitry of the laser transmitter system 100. Operation of the laser transmitter system 100 involves generating narrow pulses of laser energy using the laser diode. To generate the narrow pulses, the laser drivers 104 switch the laser diodes on and off.

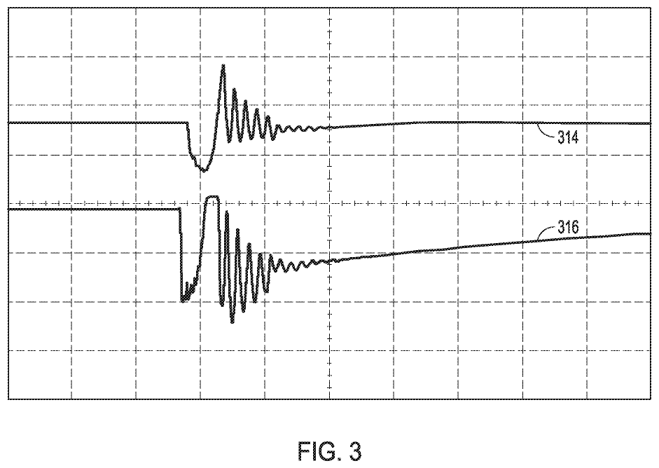

FIGS. 2A and 2B are schematics of examples of laser driver circuit topologies to control a laser transmitter system. Several options exist for the laser driver circuits, and FIGS. 2A and 2B show single switch circuit topologies that include a field effect transistor (FET). In the examples of FIGS. 2A and 2B the switching circuits include an n-channel FET (e.g., an n-channel metal oxide semiconductor FET (MOSFET)). In FIGS. 2A and 2B the block labeled “Load” represents the laser diode, which can include a VCSEL diode or an EEL diode. FIG. 2A shows a low-side switch circuit in which the FET 210 is positioned between the Load and circuit ground. FIG. 2B shows a high-side switch circuit in which the FET 210 is positioned between the circuit supply (VDD) and the Load. The laser transmitter systems of FIGS. 2A and 2B are very susceptible to system parasitics during turning on and turning off the switches.

FIGS. 2A and 2B show inductors 212 representing unwanted parasitic inductances in the systems. When switching occurs in the circuits of FIGS. 2A and 2B, the charge stored in the capacitors 208 goes through a parasitic current loop or “hot loop.” FIGS. 2A and 2B show the hot loop from the capacitors 208 through the parasitic inductances to ground and returned through circuit ground to the capacitors 208. During turn-on, parasitic inductance and capacitance limits the rise time or the turn-on time of the laser diode. For each of the parasitic inductances shown in FIGS. 2A and 2B, a voltage drop occurs accord to

V_{L}=(di/dt)L,

where L is the parasitic inductance and i is the current through the parasitic inductance. These voltage drops limit the fast rise times available with the laser diodes

During turn-off, the parasitic inductances and capacitances can cause voltage jumps that might damage the switching transistors (e.g., the FETs) or the laser diode. When the switching transistor is ON, current passes through the hot loop path for a period of time. When the switching transistor turns off, current stored in the parasitic inductances needs to flow through some leakage path, and voltage overshoots and undershoots can occur as a result.

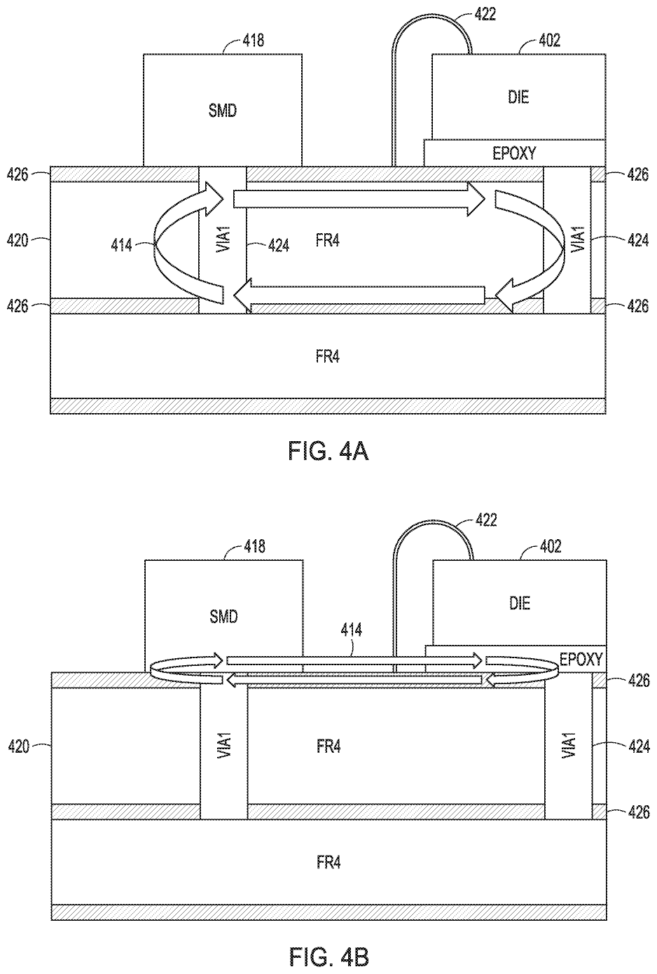

FIG. 3 is a timing diagram of an example of turning on and turning off a low-side switch circuit. The top waveform 314, shows the ringing of current that can occur when the switching transistor is turned on and off. The lower waveform 316, shows the ringing of the drain voltage of the switching transistor. The ringing can damage and stress parts such as the switching transistors and the laser diodes.

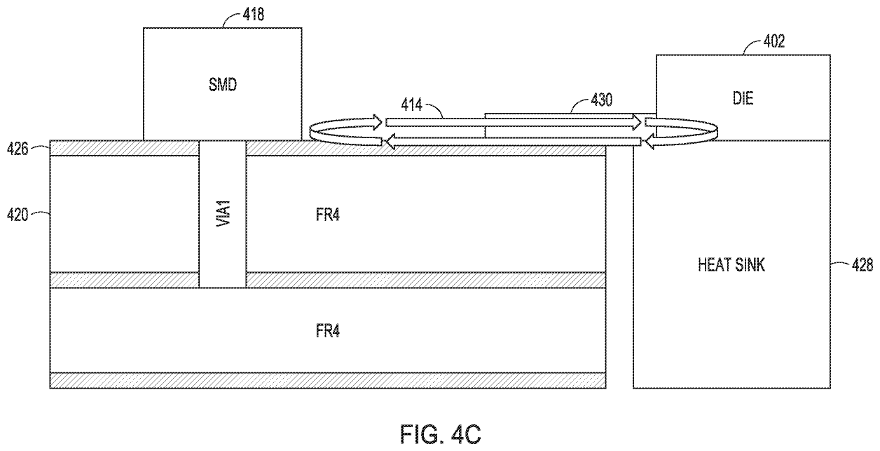

FIGS. 4A-4C are examples of circuit assemblies with laser diodes. In the examples, the circuit assemblies include long wirebonds, additional vias, long metal traces or leads that all can introduce circuit parasitics; mostly parasitic inductances. In FIG. 4A, a surface mount device (SMD 418) and a laser diode (DIE 402) are mounted on the top surface of a printed circuit board (PCB 420). The SMD can include one or more circuits such as a high-side switch circuit or a low-side switch circuit. The laser DIE 402 may be mounted on the PCB 420 using a conductive epoxy. The assembly in FIG. 4A includes long wirebonds 422 from the top surface of the PCB 420 to the top surface of the laser DIE 402, which may be the anode of the laser diode. The cathode may be on the bottom surface of the laser diode may contact the conductive epoxy. The laser DIE may be an edge emitting laser diode that emits laser energy from the side of the laser DIE 402. The laser DIE may be a vertical cavity emitting laser diode that emits laser energy from the top of the laser DIE 402. The assembly also includes vias 424 and conductive traces 426 of the PCB. FIG. 4A also shows an example of a vertical current loop 414 (hot loop) that includes the laser DIE 402, the vias 424, the conductive traces 426, and the wirebonds 422. It can be seen in FIG. 4A that a current loop may form in multiple layers of the assembly. FIG. 4B is the same assembly as FIG. 4A but shows an example of a horizontal current loop 414 that forms in a single layer of the assembly.

FIG. 4C is an example of a circuit assembly for a laser diode that includes the SMD 418 on the PCB 420 and the laser DIE 402 placed on a heatsink 428 external to the circuit substrate. A lead 430 is used to electrically couple the conductive traces 426 of the PCB 420 to the laser DIE 402. FIG. 4C shows an example of a horizontal current loop 414 that can form in the assembly.

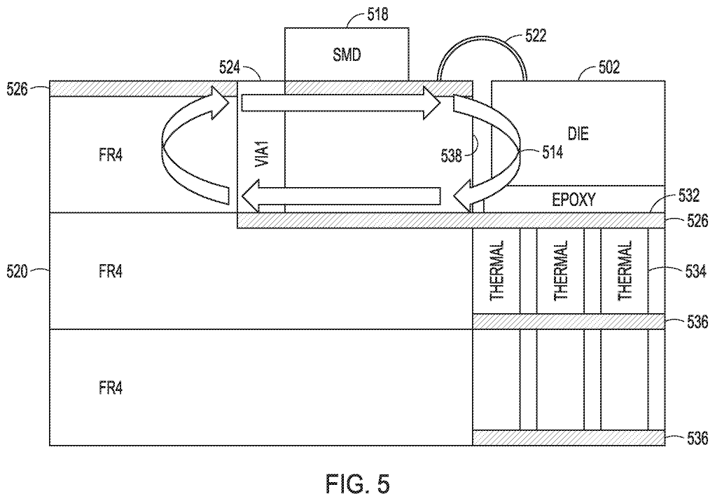

FIG. 5 is an example of a circuit assembly with a laser diode that minimizes the paths available for a current loop and reduces parasitics. The circuit assembly includes a laser DIE 502, an SMD 518, and a circuit substrate 520. The circuit substrate 520 may be a PCB, a laminated substrate, or a silicon substrate. The circuit substrate 520 includes a top surface and a bottom surface and the SMD 518 is mounted on the top surface. The circuit substrate 520 includes a cavity on the edge of the circuit substrate 520. The cavity exposes an intermediate surface 532 between the top surface and the bottom surface of the circuit substrate 520.

The top surface of the laser DIE 502 is the laser diode anode and the bottom surface of the laser DIE 502 is the laser diode cathode. The bottom surface of the laser DIE 502 is mounted on the intermediate surface 532 of the laser DIE 502. The laser DIE 502 has a side surface. The laser DIE 502 may be an edge emitting laser diode that emits laser energy from the side surface in a direction parallel to the top surface of the circuit substrate 520 and away from the cavity wall or walls formed by the circuit substrate. The example of FIG. 5 shows one cavity wall 538, but the cavity may have one, two, or three walls. One side of the laser DIE 502 is exposed by the cavity of the circuit substrate 520 to allow the laser energy to be emitted from the side of the laser DIE 502. The laser DIE 502 may be a vertical cavity surface emitting laser diode that emits laser energy from the top surface in a direction perpendicular to the top surface of the circuit substrate 520.

The top surface of the laser diode is substantially aligned with the top surface of the circuit substrate 520 so that the length of the wirebonds 522 is reduced or minimized to reduce the parasitic inductance associated with the wirebonds 522. Because the top surface of the laser diode is aligned with the top surface of the circuit substrate 520, the top surface of the laser DIE 502 may be aligned below the bottom surface of the SMD 518.

Also, one via or one set of vias (the via on the right in FIGS. 4A and 4B) is no longer needed because of the placement of the laser DIE 502 between the top surface of the circuit substrate 520 and the conductive traces 526 of the intermediate surface 532. The conductive traces may comprise a metal (e.g., copper or aluminum). The top surface of the laser DIE 502 and the top surface of the remaining via 524 are aligned with the top surface of the circuit substrate 520. The height of the via 524 can be limited to the height of the cavity wall. The height of the via 524 can be limited to the height of the laser DIE 502. There are no signal vias positioned under the laser DIE 502. Removing the via or vias reduces the parasitic inductance associated with the vias. The current loop 514 from the bottom of the laser DIE 502, through the conductive trace 526 of the intermediate surface, the remaining via 524, and the conductive trace 526 on the top surface of the circuit substrate 520 is closed by the laser DIE 502. This closes the current loop with minimized trace length and minimized parasitic inductance. Thus, the approach of the circuit assembly of FIG. 5 reduces the limiting by the parasitics of the fast rise times available with the laser diodes (e.g., pulses with widths in the nanosecond (ns) range) and reduces the overshoot and undershoot that may damage the circuit components of the laser transmitter system.

The additional layers shown in FIG. 5 are optional. Heat from the laser DIE 502 can be transferred through the thermal vias 534 and additional conductive layers 536 or conductive planes. The additional conductive layers 536 are minimized to minimize any parasitic capacitance introduced by the additional conductive layers 536.

If a high-side switch circuit as in the example of FIG. 2B is used in the circuit assembly of FIG. 5, the bottom surface of the laser DIE 502 and the cathode of the laser diode can be electrically connected to circuit ground. The thermal vias 534 and the additional conductive traces 536 can also be connected to circuit ground. If a low-side switch circuit as in the example of FIG. 2A is used in the circuit assembly of FIG. 5, the bottom surface of the laser DIE 502 is not electrically connected to circuit ground. Parasitics associated with the thermal vias 534 and the additional conductive traces 536 should be minimized.

Different approaches can be used to minimize the parasitics. The thermal vias 534 can be sized and shaped to minimize the parasitics. The thermal vias 534 can be formed using a thermally conductive but non-electrically conductive material. The additional conductive traces 536 or conductive planes can be removed or a thermally conducting but not electrically conducting adhesive can be used at the top of the thermal vias 534 to block any electrical paths into the thermal vias 534.

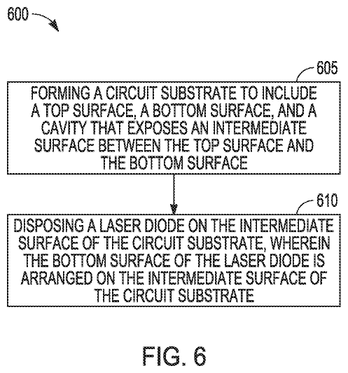

FIG. 6 is a flow diagram of an example of a method 600 of making a circuit assembly that includes a laser diode. At 605, a circuit substrate is formed to include a top surface, a bottom surface, and a cavity that exposes an intermediate surface between the top surface and the bottom surface. The cavity may have one wall and may run along the edge of the circuit substrate. The cavity may have two walls and may be formed at a corner of the circuit substrate. The cavity may have three walls and may be a notch at the edge of the circuit substrate.

In some aspects, the circuit substrate is a PCB including multiple layers. The top of the PCB is formed smaller than the next lower layer of the PCB to leave the intermediate layer exposed. In some aspects, the circuit substrate is a silicon substrate and a top surface of the silicon substrate is partially etched to expose the intermediate surface.

At 610, a laser diode is disposed on the intermediate surface of the circuit substrate. In certain aspects, conductive epoxy is used to the mount the laser diode on the intermediate surface. The bottom surface of the laser diode is arranged on the intermediate surface of the circuit substrate, and the top surface of the laser diode is aligned with the top surface of the circuit substrate. In certain aspects, the laser diode is an edge emitting laser diode. Laser energy of the edge emitting laser diode is emitted from the side surface of the laser diode (e.g., parallel to the top surface of the circuit substrate. In certain aspects, the laser diode is a vertical cavity surface emitting laser diode. Laser energy of the edge emitting laser diode is emitted from the top surface of the laser diode (e.g., perpendicular to the top surface of the circuit substrate).

A surface mount device (SMD) can be arranged on the top surface of the circuit substrate. The SMD can include one or more of a low-side switch circuit and a high-side switch circuit to control the switching of the laser diode. In some aspects, the method 600 includes forming one or more signal vias in the portion of the circuit substrate above the intermediate layer. As shown in FIG. 5 conductive interconnect can be formed on the intermediate surface and the top surface of the circuit substrate to contact the signal vias. The signal vias can provide electrical continuity between the bottom surface of the laser diode and the SMD. The signal vias may have the same height as the edge emitting laser diode. In some aspects, wirebonds are formed to electrically connect the laser diode (e.g., connect the anode) to conductive interconnect of the top surface of the circuit substrate. In some aspects, the bottom surface of the laser diode is electrically connected to circuit ground. In some aspects, the bottom surface of the laser diode is electrically connected to a low-side switch circuit (e.g., a low-side switch circuit included in the SMD).

In some aspects forming the circuit substrate includes forming one or more thermal vias in the circuit substrate below the intermediate surface. In certain aspects, electrically conductive traces or electrically conductive planes are formed in the circuit substrate to contact the thermal vias. The thermal vias and the cathode may be electrically connected to circuit ground, such as when the edge emitting laser diode is driven using a high side switch. In certain aspects, the edge emitting laser diode is driven using a low side switch. In this case, the thermal vias are not electrically conductive but are still thermally conductive. In certain aspects, the thermal vias are electrically and thermally conductive and a non-electrically conductive material is placed between the intermediate surface and the thermal vias.

The circuit assembly formed reduces parasitic inductances and capacitances that limit performance of the edge emitting laser diode. With the reduced parasitics, power levels of the laser diodes can be increased within narrow pulses of ON time of the laser diodes.

### ADDITIONAL DESCRIPTION AND ASPECTS

Aspect 1 includes subject matter (such as an electronic assembly) comprising a circuit substrate and a laser diode. The circuit substrate includes a top surface, a bottom surface, and a cavity formed at an edge of the circuit substrate that exposes an intermediate surface between the top surface and the bottom surface of the circuit substrate. The laser diode includes a top surface, a bottom surface, and a side surface, and the bottom surface of the laser diode is arranged on the intermediate surface of the circuit substrate.

In Aspect 2, the subject matter of Aspect 1 optionally includes an edge emitting laser diode configured to emit laser energy from a side surface of the laser diode, the bottom surface of the edge emitting laser diode is arranged on the intermediate surface of the circuit substrate and the top surface of the edge emitting laser diode is substantially aligned with the top surface of the circuit substrate.

In Aspect 3, the subject matter of Aspect 2 optionally includes a circuit substrate including one or more signal vias extending from a height of the intermediate surface to the top surface of the circuit substrate.

In Aspect 4, the subject matter of Aspect 3 optionally includes one or more signal vias with a height substantially equal to a height of the edge emitting laser diode.

In Aspect 5, the subject matter of one or both of Aspects 3 and 4 optionally includes a surface mount device (SMD) disposed on the top surface of the circuit substrate. The intermediate surface of the circuit substrate includes one or more electrically conductive traces electrically connected to the bottom surface of the edge emitting laser diode. The top surface of the circuit substrate includes one or more one or more electrically conductive traces electrically connected to the SMD, and at least one via of the one or more signal vias provide electrical continuity between the bottom surface of the edge emitting laser diode and the SMD.

In Aspect 6, the subject matter of one or any combination of Aspects 1-5 optionally includes the cavity of the circuit substrate having one wall extending along the edge of the circuit substrate.

In Aspect 7, the subject matter of one or any combination of Aspects 1-5 optionally includes the cavity of the circuit substrate positioned at a corner of the circuit substrate and the cavity including two walls.

In Aspect 8, the subject matter of one or any combination of Aspects 1-5 optionally includes the cavity of the circuit substrate is a notch in the circuit substrate that is arranged at the edge of the circuit substrate and includes three walls.

In Aspect 9, the subject matter of one or any combination of Aspects 1-8 optionally includes a surface mount device (SMD) disposed on the top surface of the circuit substrate and including a high side switch to drive the laser diode, and one or more thermal vias disposed below the intermediate surface of the circuit substrate and under the laser diode. The bottom surface of the laser diode and the thermal vias are connected to circuit ground.

In Aspect 10, the subject matter of one or any combination of Aspects 1-8 optionally includes a surface mount device (SMD) disposed on the top surface of the circuit substrate and including a low side switch to drive the laser diode. The electronic assembly includes one or more electrically conductive traces disposed on the intermediate surface and electrically connected to the bottom surface of the laser diode, one or more thermal vias disposed below the intermediate surface of the circuit substrate and under the laser diode, and a thermally conducting and electrically non-conducting layer positioned between the bottom surface of the laser diode and the one or more thermal vias.

In Aspect 11, the subject matter of one or any combination of Aspects 1-8 optionally includes a surface mount device (SMD) disposed on the top surface of the circuit substrate and including a low side switch to drive the laser diode. The electronic assembly includes one or more electrically conductive traces disposed on the intermediate surface and electrically connected to the bottom surface of the laser diode, and one or more thermal vias disposed below the intermediate surface of the circuit substrate and under the laser diode. The thermal vias comprise a thermally conductive and electrically non-conductive material.

Aspect 12 includes subject matter (such as a method of making an electronic circuit assembly) or can optionally be combined with one or any combination of Aspects 1-11 to include such subject matter, comprising forming a circuit substrate to include a top surface, a bottom surface, and a cavity that exposes an intermediate surface between the top surface and the bottom surface, and disposing an edge emitting laser diode on the intermediate surface of the circuit substrate. A bottom surface of the laser diode is arranged on the intermediate surface of the circuit substrate, and the top surface of the laser diode is aligned with the top surface of the circuit substrate.

In Aspect 13, the subject matter of Aspect 12 optionally includes disposing an edge emitting laser diode on the intermediate surface of the circuit substrate.

In Aspect 14, the subject matter of one or both of Aspects 12 and 13 optionally includes forming the circuit substrate to include a cavity having one wall extending along the edge of the circuit substrate.

In Aspect 15, the subject matter of one or both of Aspects 12 and 13 optionally includes forming the circuit substrate to include a cavity having two walls and positioned at a corner of the circuit substrate.

In Aspect 16, the subject matter of one or both of Aspects 12 and 13 optionally includes forming the circuit substrate to include a notch at the edge of the circuit substrate as the cavity that exposes the intermediate surface.

In Aspect 17, the subject matter of one or any combination of Aspects 12-16 optionally includes disposing an edge emitting laser diode on the intermediate surface of the circuit substrate so that a top surface of the edge emitting laser diode is substantially aligned with the top surface of the circuit substrate, and forming one or more signal vias in the circuit substrate. The one or more signal vias have a height substantially equal to a height of the edge emitting laser diode and extending from the top surface of the circuit substrate to a height of the intermediate surface of the circuit substrate.

In Aspect 18 the subject matter of Aspect 17 optionally includes forming electrically conductive interconnect on the intermediate surface and the top surface of the circuit substrate to contact the one or more signal vias, and disposing a surface mount device (SMD) on the top surface of the circuit substrate so that the one or more signal vias provide electrical continuity between the bottom surface of the edge emitting laser diode and the SMD.

In Aspect 19, the subject matter of Aspect 18 optionally includes disposing one or both of electrically conductive traces and electrically conductive planes in the circuit substrate and disposing one or more thermal vias below the intermediate surface of the cavity of the circuit substrate and under the edge emitting laser diode. The one or more thermal vias are electrically connected to the one or both of the electrically conductive traces and electrically conductive planes.

In Aspect 20, the subject matter of Aspect 19 optionally includes disposing a surface mount device (SMD) on the top surface of the circuit substrate that includes a high side switch to drive the edge emitting laser diode, and electrically connecting the bottom surface of the edge emitting laser diode, the one or more thermal vias, and at least one of the electrically conductive traces and electrically conductive planes to circuit ground.

In Aspect 21, the subject matter of one or any combination of Aspects 12-17 optionally includes disposing one or more thermal vias below the intermediate surface of the cavity of the circuit substrate and under the edge emitting laser diode. The one or more thermal vias comprise a thermally conductive and electrically non-conductive material. The subject matter further includes disposing a surface mount device (SMD) on the top surface of the circuit substrate that includes a low side switch to drive the edge emitting laser diode.

In Aspect 22, the subject matter of one or any combination of Aspects 12-17 optionally includes disposing one or more thermal vias below the intermediate surface of the cavity of the circuit substrate and under the edge emitting laser diode, disposing a surface mount device (SMD) on the top surface of the circuit substrate that includes a low side switch to drive the edge emitting laser diode, and disposing a thermally conducting and electrically non-conducting layer between the bottom surface of the edge emitting laser diode and the one or more thermal vias.

Aspect 23 includes subject matter (such as a laser transmitter system) or can optionally be combined with one or any combination of Aspects 1-22 to include such subject matter, comprising a circuit substrate including a top surface, a bottom surface, and a cavity formed at an edge of the circuit substrate that exposes an intermediate surface between the top surface and the bottom surface of the circuit substrate, an edge emitting laser diode including a top surface, a bottom surface, and a side surface facing away from a wall of the cavity, wherein laser energy of the laser diode is emitted from the side surface of the laser diode; the bottom surface of the laser diode is arranged on the intermediate surface of the circuit substrate, and the top surface of the laser diode is aligned with the top surface of the circuit substrate; one or more wire bonds connecting the top surface of the edge emitting laser diode to the top surface of the circuit substrate; a surface mount device (SMD) disposed on the top surface of the circuit substrate; and one or more signal vias extending in the circuit substrate from a height of the intermediate surface to the top surface of the circuit substrate, where the one or more signal vias provide electrical continuity between the bottom surface of the edge emitting laser diode and the SMD.

In Aspect 24, the subject matter of Aspect 23 optionally includes an SMD including a high side switch to drive the edge emitting laser diode, and the bottom surface of the edge emitting laser diode is electrically connected to circuit ground.

In Aspect 25, the subject matter of Aspect 23 optionally includes an SMD including a low side switch to drive the edge emitting laser diode, and the bottom surface of the edge emitting laser diode is electrically connected to circuit ground.

These non-limiting Aspects can be combined in any permutation or combination. The above detailed description includes references to the accompanying drawings, which form a part of the detailed description. The drawings show, by way of illustration, specific embodiments in which the invention can be practiced. These embodiments are also referred to herein as “examples” or “aspects.” All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of“at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. Method examples described herein can be machine or computer-implemented at least in part.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

What is claimed is:

1. An electronic circuit assembly, comprising:
a circuit substrate including a top surface, a bottom surface, and a cavity formed at an edge of the circuit substrate that exposes an intermediate surface between the top surface and the bottom surface of the circuit substrate; and
a laser diode including a top surface, a bottom surface, and a side surface,
wherein the bottom surface of the laser diode is arranged on the intermediate surface of the circuit substrate.

2. The electronic assembly of claim 1, wherein the laser diode is an edge emitting laser diode configured to emit laser energy from a side surface of the laser diode, and the top surface of the edge emitting laser diode is substantially aligned with the top surface of the circuit substrate.

3. The electronic circuit assembly of claim 2, wherein the circuit substrate includes one or more signal vias extending from a height of the intermediate surface to the top surface of the circuit substrate.

4. The electronic circuit assembly of claim 3, wherein a height of the one or more signal vias is substantially equal to a height of the edge emitting laser diode.

5. The electronic circuit assembly of claim 3, including:
a surface mount device (SMD) disposed on the top surface of the circuit substrate;
wherein the intermediate surface of the circuit substrate includes one or more electrically conductive traces electrically connected to the bottom surface of the edge emitting laser diode; the top surface of the circuit substrate includes one or more one or more electrically conductive traces electrically connected to the SMD; and at least one via of the one or more signal vias provide electrical continuity between the bottom surface of the edge emitting laser diode and the SMD.

6. The electronic circuit assembly of claim 1, wherein the cavity has one wall extending along the edge of the circuit substrate.

7. The electronic circuit assembly of claim 1, wherein the cavity is positioned at a corner of the circuit substrate and includes two walls.

8. The electronic circuit assembly of claim 1, wherein the cavity is a notch in the circuit substrate arranged at the edge of the circuit substrate and includes three walls.

9. The electronic circuit assembly of claim 1, including:
a surface mount device (SMD) disposed on the top surface of the circuit substrate and including a high side switch to drive the laser diode;
one or more thermal vias disposed below the intermediate surface of the circuit substrate and under the laser diode; and
wherein the bottom surface of the laser diode and the thermal vias are connected to circuit ground.

10. The electronic circuit assembly of claim 1, including:
a surface mount device (SMD) disposed on the top surface of the circuit substrate and including a low side switch to drive the laser diode;
one or more electrically conductive traces disposed on the intermediate surface and electrically connected to the bottom surface of the laser diode;
one or more thermal vias disposed below the intermediate surface of the circuit substrate and under the laser diode; and
a thermally conducting and electrically non-conducting layer positioned between the bottom surface of the laser diode and the one or more thermal vias.

11. The electronic circuit assembly of claim 1, including:
a surface mount device (SMD) disposed on the top surface of the circuit substrate and including a low side switch to drive the laser diode;
one or more electrically conductive traces disposed on the intermediate surface and electrically connected to the bottom surface of the laser diode; and
one or more thermal vias disposed below the intermediate surface of the circuit substrate and under the laser diode, wherein the thermal vias comprise a thermally conductive and electrically non-conductive material.

12. A method of making an electronic circuit assembly, the method comprising:
forming a circuit substrate to include a top surface, a bottom surface, and a cavity that exposes an intermediate surface between the top surface and the bottom surface, and
disposing an edge emitting laser diode on the intermediate surface of the circuit substrate, wherein a bottom surface of the laser diode is arranged on the intermediate surface of the circuit substrate, and the top surface of the laser diode is aligned with the top surface of the circuit substrate.

13. The method of claim 12, wherein disposing the laser diode includes disposing an edge emitting laser diode on the intermediate surface of the circuit substrate.

14. The method of claim 13, wherein forming the circuit substrate includes forming the circuit substrate to include a cavity having one wall extending along the edge of the circuit substrate.

15. The method of claim 13, wherein forming the circuit substrate includes forming the circuit substrate to include a cavity having two walls and positioned at a corner of the circuit substrate.

16. The method of claim 13, wherein forming the circuit substrate includes forming the circuit substrate to include a notch at the edge of the circuit substrate as the cavity that exposes the intermediate surface.

17. The method of claim 12,
wherein disposing the laser diode includes disposing an edge emitting laser diode on the intermediate surface of the circuit substrate so that a top surface of the edge emitting laser diode is substantially aligned with the top surface of the circuit substrate; and
the method further including forming one or more signal vias in the circuit substrate, the one or more signal vias having a height substantially equal to a height of the edge emitting laser diode and extending from the top surface of the circuit substrate to a height of the intermediate surface of the circuit substrate.

18. The method of claim 17, including:
forming electrically conductive interconnect on the intermediate surface and the top surface of the circuit substrate to contact the one or more signal vias; and
disposing a surface mount device (SMD) on the top surface of the circuit substrate so that the one or more signal vias provide electrical continuity between the bottom surface of the edge emitting laser diode and the SMD.

19. The method of claim 17, including:
disposing one or both of electrically conductive traces and electrically conductive planes in the circuit substrate; and
disposing one or more thermal vias below the intermediate surface of the cavity of the circuit substrate and under the edge emitting laser diode, wherein the one or more thermal vias are electrically connected to the one or both of the electrically conductive traces and electrically conductive planes.

20. The method of claim 19, including:
disposing a surface mount device (SMD) on the top surface of the circuit substrate that includes a high side switch to drive the edge emitting laser diode; and
electrically connecting the bottom surface of the edge emitting laser diode, the one or more thermal vias, and at least one of the electrically conductive traces and electrically conductive planes to circuit ground.

21. The method of claim 13, including:
disposing one or more thermal vias below the intermediate surface of the cavity of the circuit substrate and under the edge emitting laser diode, wherein the one or more thermal vias comprise a thermally conductive and electrically non-conductive material; and
disposing a surface mount device (SMD) on the top surface of the circuit substrate that includes a low side switch to drive the edge emitting laser diode.

22. The method of claim 13, including:
disposing one or more thermal vias below the intermediate surface of the cavity of the circuit substrate and under the edge emitting laser diode;
disposing a surface mount device (SMD) on the top surface of the circuit substrate that includes a low side switch to drive the edge emitting laser diode; and
disposing a thermally conducting and electrically non-conducting layer between the bottom surface of the edge emitting laser diode and the one or more thermal vias.

23. A laser transmitter system, comprising:
a circuit substrate including a top surface, a bottom surface, and a cavity formed at an edge of the circuit substrate that exposes an intermediate surface between the top surface and the bottom surface of the circuit substrate;
an edge emitting laser diode including a top surface, a bottom surface, and a side surface facing away from a wall of the cavity, wherein laser energy of the laser diode is emitted from the side surface of the laser diode; the bottom surface of the laser diode is arranged on the intermediate surface of the circuit substrate, and the top surface of the laser diode is aligned with the top surface of the circuit substrate:
one or more wire bonds connecting the top surface of the edge emitting laser diode to the top surface of the circuit substrate;
a surface mount device (SMD) disposed on the top surface of the circuit substrate; and
one or more signal vias extending in the circuit substrate from a height of the intermediate surface to the top surface of the circuit substrate, where the one or more signal vias provide electrical continuity between the bottom surface of the edge emitting laser diode and the SMD.

24. The laser transmitter system of claim 23, wherein the SMD includes a high side switch to drive the edge emitting laser diode, and the bottom surface of the edge emitting laser diode is electrically connected to circuit ground.

25. The laser transmitter system of claim 23, wherein the SMD includes a low side switch to drive the edge emitting laser diode, and the bottom surface of the edge emitting laser diode is electrically connected to circuit ground.
